(19) United States
(12) Patent Application Publication
(10) Pub. No.: US 2026/0130234 A1
(43) Pub. Date: May 7, 2026

(54) SEMICONDUCTOR DEVICE ASSEMBLIES WITH DIE ADHESIVE OUTFLOW BARRIERS

(71) Applicant: SEMICONDUCTOR COMPONENTS INDUSTRIES, LLC, Scottsdale, AZ (US)

(72) Inventors: Sixin JI, NanTong (CN); Jie CHANG, Suzhou (CN); Yanghai TIAN, Suzhou City (CN); Keunhyuk LEE, Suzhou (CN); Gyuwan HAN, Incheon (KR); JeongHyuk PARK, Incheon (KR)

(73) Assignee: SEMICONDUCTOR COMPONENTS INDUSTRIES, LLC, Scottsdale, AZ (US)

(21) Appl. No.: 18/935,858

(22) Filed: Nov. 4, 2024

(51) Int. Cl. H01L 23/00; H01L 23/495; H01L 23/498; H01L 25/16

(52) U.S. Cl. CPC H10W 70/417; H10W 70/481; H10W 70/658; H10W 90/00; H10W 72/387; H10W 90/734; H10W 90/736; H10W 90/764; H10W 90/766

(57) ABSTRACT

In a general aspect, a semiconductor device assembly includes a conductive member, a conductive adhesive disposed on the conductive member, and a semiconductor die disposed on the conductive adhesive. The conductive adhesive couples the semiconductor die with the conductive member. The device assembly further includes a barrier included in the conductive member. The barrier is proximate to an edge of the semiconductor die and configured to inhibit outflow of the conductive adhesive.

### SUMMARY

In a general aspect, a semiconductor device assembly includes a conductive member, a conductive adhesive disposed on the conductive member, and a semiconductor die disposed on the conductive adhesive. The conductive adhesive couples the semiconductor die with the conductive member. The device assembly further includes a barrier included in the conductive member. The barrier is proximate to an edge of the semiconductor die and configured to inhibit outflow of the conductive adhesive.

In another general aspect, a semiconductor device assembly includes a conductive member having a primary surface arranged along a transverse axis and a longitudinal axis, and a barrier included in the conductive member. The barrier is arranged along the transverse axis and extends from a first edge of the conductive member to a second edge of the conductive member opposite the first edge. The barrier divides the primary surface into a first die attach surface and a second die attach surface. The device assembly further includes a first conductive adhesive disposed on the first die attach surface proximate the barrier, and a first semiconductor die disposed on the first conductive adhesive. The first conductive adhesive couples the first semiconductor die with the first die attach surface. The device assembly also includes a second conductive adhesive disposed on the second die attach surface proximate the barrier, and a second semiconductor die disposed on the second conductive adhesive. The second conductive adhesive couples the second semiconductor die with the second die attach surface. The barrier is configured to inhibit bridging of the first conductive adhesive with the second conductive adhesive.

### BRIEF DESCRIPTION OF THE DRAWINGS

FIG. 1 is a diagram illustrating an example leadframe including an outflow barrier.

FIG. 2 is a diagram schematically illustrating a cross-sectional view of a conductive member of the leadframe of FIG. 1 with a plurality of semiconductor die and corresponding die attach adhesive.

FIGS. 2A to 2G are diagrams schematically illustrating example outflow barriers.

FIGS. 3A to 3C are diagrams schematically illustrating examples of barriers blocking and/or impeding outflow of die attach adhesive outflow in respective semiconductor device assemblies.

FIG. 4 is a flowchart including schematic diagrams illustrating an example process flow for producing a semiconductor device assembly.

FIGS. 5A and 5B are diagrams illustrating, respectively, top and side views of an example semiconductor device assembly including outflow barriers.

FIGS. 6A and 6B are diagrams illustrating, respectively, top and side views of another example semiconductor device assembly including outflow barriers.

FIG. 7A is a magnified view of a portion of the semiconductor device assembly of FIGS. 5A and 5B.

FIG. 7B is a magnified view of a portion of the semiconductor device assembly of FIGS. 6A and 6B.

FIG. 8A is a further magnified view of a portion of the semiconductor assembly shown in FIG. 7A after molding compound encapsulation.

FIG. 8B is a further magnified view of a portion of the semiconductor assembly shown in FIG. 7B after molding compound encapsulation.

In the drawings, which are not necessarily drawn to scale, like reference labels may indicate like and/or similar components (elements, structures, etc.) in different views. The drawings illustrate generally, by way of example, but not by way of limitation, various implementations discussed in the present disclosure. Reference labels shown in one drawing may not be repeated for the same, and/or similar elements in related views. Reference labels that are repeated in multiple drawings may not be specifically discussed with respect to each of those drawings, but are provided for context between related views. Also, not all like elements in the drawings may be specifically referenced with a reference label when multiple instances of that element are illustrated.

### DETAILED DESCRIPTION

Packaged semiconductor device modules (semiconductor device assemblies) can include one or more semiconductor die. For example, a power semiconductor device module can include multiple semiconductor die implementing, respectively, power transistors, diodes, etc. As power requirements increase for such modules, such as for industrial or automotive applications, respective sizes of the semiconductor die can also increase while corresponding package size, form factor and/or footprint remain the same, e.g., for compatibility in existing systems configurations. Accordingly, in such implementations, spacing between semiconductor die decreases due to the increased die sizes and constant package size, including a constant size of a conductive member (die attach paddle, substrate, etc.) on which the semiconductor die are attached (coupled, mounted, etc.) in the device assembly. This decrease in die spacing can result in issues that affect quality and/or reliability of a corresponding semiconductor device module.

For instance, such decreased spacing can result in bridging of die-attach adhesive (e.g., solder material, sintering material, conductive epoxy, etc.) of one semiconductor die with die attach adhesive of another, adjacent semiconductor die, e.g., due to outflow of the die attach adhesives during a die attach process. Such bridging, e.g., as a result of self-surface tension of the bridged die attach adhesives, can cause a number of issues. Such issues can include insufficient die attach coverage for at least a portion of one or more of the semiconductor die, poor die attach thickness control (e.g., bond line thickness control), and/or die tilt. Such issues can then lead to quality and reliability issues, such wire bond damage or lift off, die attach adhesive voiding, and/or die cracking, which can result detrimental effects on device operation or device failure. While described with respect to device assemblies including a plurality of semiconductor die, such issues can affect devices with one, or multiple semiconductor die.

Additionally, outflow of die-attach adhesive, e.g., from under a semiconductor die, can increase risk of delamination of a molding compound used to encapsulate portions of a semiconductor device assembly. Such delamination can occur due to lack of adhesion between a molding compound (e.g., an epoxy molding compound) and the die attach adhesive, e.g., at an interface between a molding compound encapsulant and the die attach adhesive. Delamination of a molding compound can also cause reliability issues, such as die cracking, wire bond lifting, wire bond damage, etc.

This disclosure is directed to semiconductor device packages, modules, assemblies, etc. that can address at least some of the technical problems of prior implementations, such as those noted above. That is, this disclosure is directed to packages that include a barrier and/or structure to prevent outflow of die-attach (DA) adhesive during a die attach process as one technical solution to the foregoing described technical problems. Such barriers may be referred to herein as an outflow barrier, an adhesive outflow barrier, a barrier, and so forth.

Prior implementations have used a resist material (e.g., a chemical surface treatment, a surface coating, etc.) to prevent DA, e.g., from under a semiconductor die, from flowing onto and/or adhering with areas of a die attach surface of a conductive member outside a perimeter of a corresponding semiconductor die (e.g., other than for a desired DA adhesive fillet disposed around a perimeter of the semiconductor die). However, such resist materials are not effective in semiconductor device assembly manufacturing processes that include high temperature DA operations (e.g., at temperatures greater than 300° C.), such as high-temperature solder reflow operations, high temperature epoxy cure operations, and/or high-temperature pressure sintering operations. For instance such resist materials, e.g., solder resist materials, breakdown, degrade and/or vaporize when exposed to such high temperatures.

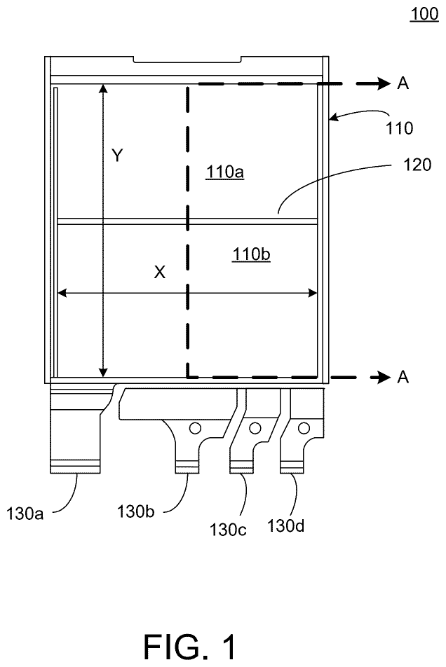

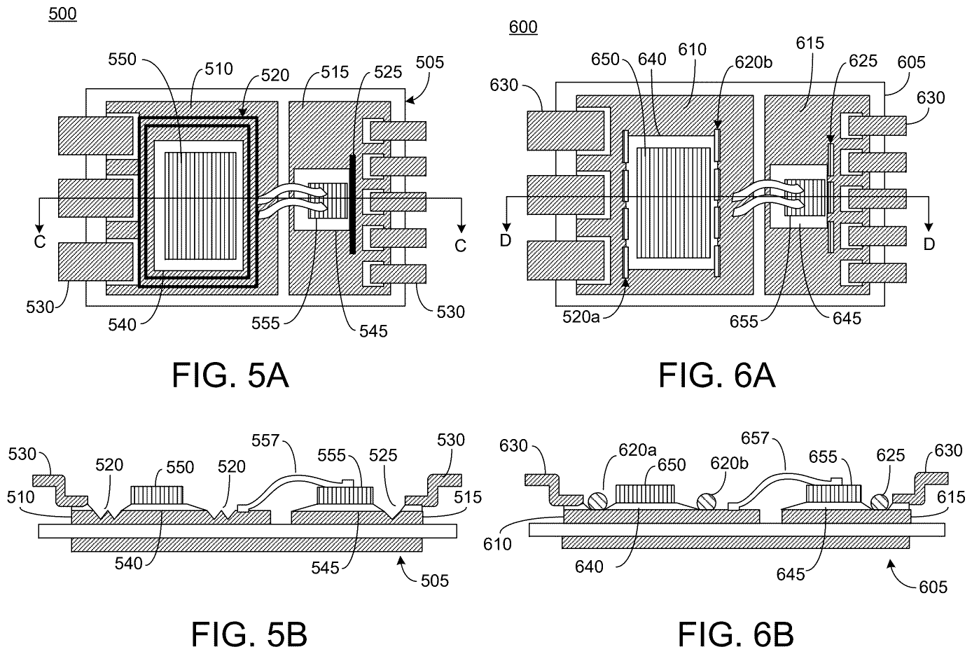

FIG. 1 illustrates a leadframe 100 for a semiconductor device assembly (package, module, etc.). In some implementations, the leadframe 100 can be a copper leadframe, or can include other electrically conductive materials. As shown in FIG. 1, the leadframe 100 includes a die attach paddle 110, which can be generally referred to as a conductive member. In some implementations, such as the examples of FIGS. 5A-5B and 6A-6B, a conductive member can be a metal layer of a direct-bonded metal (DBM) substrate.

In the example of FIG. 1, the leadframe 100 further includes a barrier 120 that is included in (formed in, disposed on, monolithically formed with, etc.) the die attach paddle 110. As shown in FIG. 1, an overall size of the die attach paddle 110, which includes the die attach surface 110a, the die attach surface 110b and the barrier 120, can have dimensions of X (along a transverse or first axis) by Y (along a longitudinal or second axis). As indicated above, as power requirements and corresponding die sizes increase, in some implementations, the X and Y dimensions for the leadframe 100 can be the same as a leadframe without a barrier that is used with smaller semiconductor die with low power ratings. That is, a same leadframe 100 with a same size die attach paddle 110, e.g., with the barrier 120, can be used in order to maintain a constant form factor with previous, lower power semiconductor device assemblies.

In this example, the barrier 120 defines a die attach surface 110a and a die attach surface 110b of the die attach paddle 110. That is, the barrier 120 divides a primary surface of the die attach paddle 110 into the die attach surface 110a and the die attach surface 110b. The barrier 120 can, during a die attach process, limit or prevent outflow of DA adhesive from under respective semiconductor die being coupled to the die attach surface 110a and the die attach surface 110b. In some implementations, a die attach process can include depositing DA adhesive material, placement of semiconductor die on respect DA adhesive material, and curing of the DA adhesive, e.g. by solder reflow, sintering, etc. The barrier 120 can inhibit, impede, block, interrupt, etc. outflow of DA adhesive during, for example, placement of a semiconductor die on corresponding DA adhesive, e.g., such as DA adhesive that is extruded during die placement. Furthermore, the barrier 120 can inhibit, impede, block, interrupt, etc. outflow of DA adhesive during a DA curing operation, such as those descried herein.

Accordingly, the barrier 120 can prevent bridging of DA adhesive material used to couple a first semiconductor die with the die attach surface 110a with DA adhesive material used to couple a semiconductor die with the die attach surface 110b. As a result of prevent DA adhesive bridging, DA adhesive coverage can be improved (e.g., voiding can be reduced or prevented), and risk of die tilt and associated issues with subsequently formed wire bonds or conductive clip attachment can be reduced or prevented. Furthermore, the barrier 120 can limit a surface area of DA adhesive material that is exposed outside a perimeter of an associated semiconductor dies, which can reduce the risk of molding compound delamination by reducing an area of a corresponding interface between the DA adhesive and the molding compound.

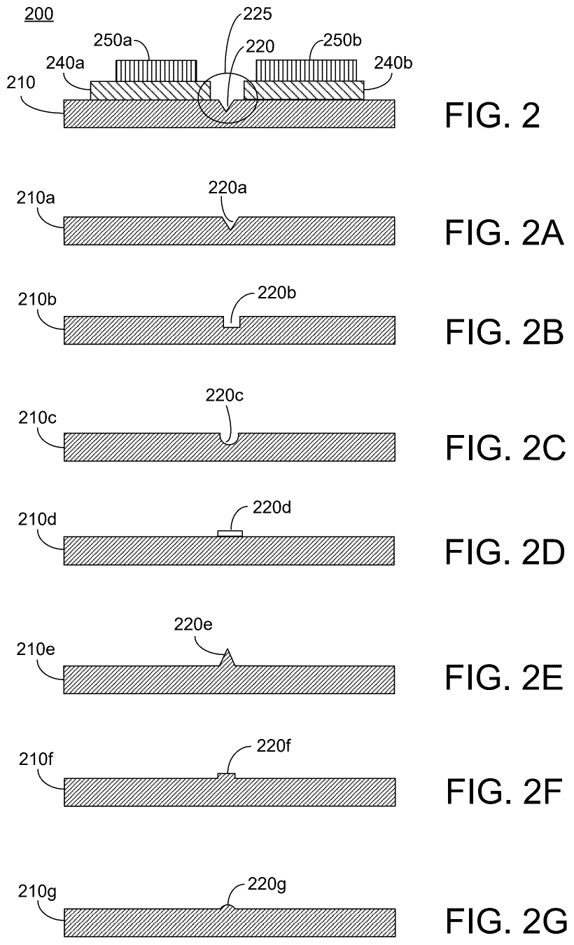

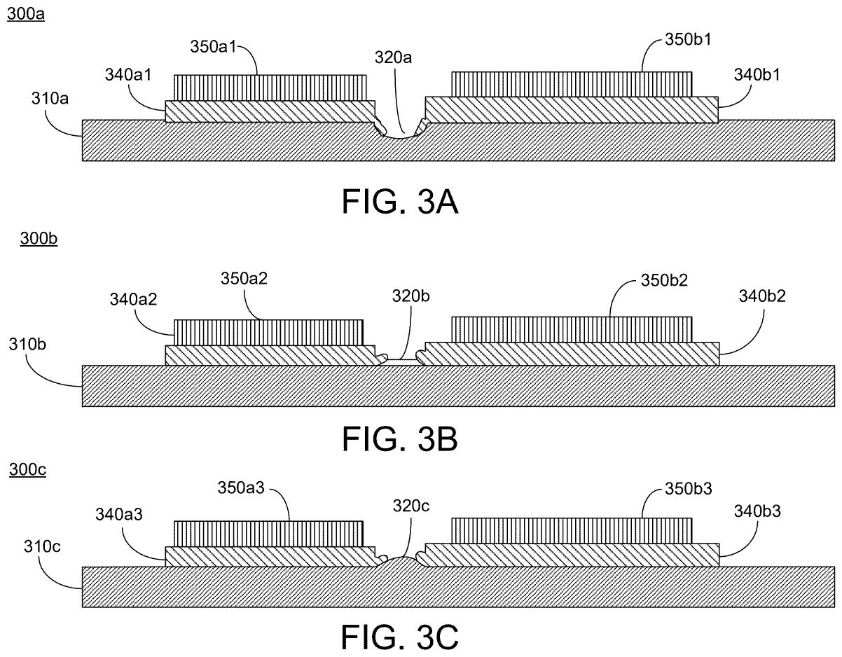

The leadframe 100 also includes a signal lead 130a, a signal lead 130b, a signal lead 130c, and a signal lead 130d. In this example, the signal lead 130a is monolithically integrated (formed, unitary, etc.) with the die attach paddle 110. That is, the signal lead 130a is electrically coupled (continuous, etc.) with the die attach paddle 110. The signal leads 130b-130d are physically (and electrically) separate from the die attach paddle 110 and, in some implementations can be electrically coupled with one or more semiconductor die coupled to the die attach paddle 110, e.g., to die attach surface 110a and/or to die attach surface 110b. FIG. 1, further illustrates a cross-section line A-A, which corresponds with the views of FIGS. 2 and 3

FIG. 2 is a diagram schematically illustrating a cross-sectional view of a semiconductor device assembly (assembly 200) that corresponds with the cross-section line A-A in FIG. 1. That is, FIG. 2 illustrates a cross-sectional view of the assembly 200 through a die attach paddle 210, which can be an implementation of the die attach paddle 110. As shown in FIG. 2, the die attach paddle 210 has a barrier 220 formed therein. The barrier 220 includes a groove defined in the die attach paddle 210. In some implementations, the barrier 220 can be formed by laser grooving, etching, mechanical grooving (e.g., with a saw), etc. As shown in FIG. 2, the barrier 220 defines a DA adhesive keep-out zone (KOZ 225), e.g., indicated by an oval in FIG. 2.

In the example of FIG. 2, the assembly 200 further includes a DA adhesive 240a, with a semiconductor die 250a disposed thereon. The assembly 200 also includes a DA adhesive 240b, with a semiconductor die 250b disposed thereon. In the view of FIG. 2, the assembly 200 is shown after respective placement of the semiconductor die 250a and the semiconductor die 250b on the DA adhesive 240a and the DA adhesive 240b, and prior to an adhesive cure operation, e.g., a solder reflow, an epoxy cure, a sintering process. In this example, the barrier 220 will inhibit the flow of the DA adhesive 240a and the DA adhesive 240b into the KOZ 225, e.g., by collecting out flow of the DA adhesive 240a and the DA adhesive 240b. Accordingly, the barrier 220 can prevent bridging of the DA adhesive 240a with the DA adhesive 240b, reducing the risk of associated quality and reliability issues. Furthermore, the barrier 220, by impeding outflow of DA adhesive, can limit respective surface areas of the DA adhesive 240a and the DA adhesive 240b that are exposed beyond the edges of the semiconductor die 250a and the semiconductor die 250b that are proximate (e.g., closest to) the barrier 220. This will, in turn, reduce respective surface areas of interfaces of the DA adhesive 240a and the DA adhesive 240b with a molding compound used to encapsulate the assembly 200 and, as a result, reduce the risk of molding compound delamination.

FIGS. 2A to 2G are diagrams schematically illustrating example conductive members, such as die attach paddles or metal layers, with various outflow barriers. For purposes of illustration, the conductive members in FIGS. 2A to 2G are shown without DA adhesive and semiconductor die. FIG. 2A illustrates a conductive member 210a that has a barrier 220a defined therein. The barrier 220a, as with the barrier 220, is a triangle shaped groove formed in a primary surface of the conductive member 210a. FIG. 2B illustrates a conductive member 210b that has a barrier 220b defined therein. The barrier 220b is a square or rectangular shaped groove formed in a primary surface of the conductive member 210b. FIG. 2C illustrates a conductive member 210c that has a barrier 220c defined therein. The barrier 220c is a semi-circle shaped groove formed in a primary surface of the conductive member 210c. The barrier 220a, the barrier 220b and the barrier 220c are given by way of example. In some implementations, a grooved barrier can have different shapes. In some implementations, a barrier can include multiple grooves formed adjacent to one another. In some implementations, the barrier 220a, the barrier 220b and/or the barrier 220c, as well as other grooved barriers described herein, can be formed by laser grooving, mechanical grooving, wet etching, dry etching, etc.

FIG. 2D illustrates a conductive member 210d that has a barrier 220d defined thereon. The barrier 220d, as compared to the barriers 220, 220a, 220b and 220c, protrudes from a primary surface of the 210d rather than including a groove or grooves defined in the primary surface. That is, in the view of FIG. 2D, the barrier 220d extends above the primary surface of the conductive member 210d. In this example, the barrier 220d can include a solder resistor, which can be disposed on and coupled to the primary surface of the barrier 220d. In some implementation, such a solder resistor barrier can include a solder material with a melting point that is greater than a melting point of a die attach adhesive that is used to couple semiconductor die with the conductive member 210d. In this example, the barrier 220d, due to its higher melting point, will not degrade at temperatures that are used to cure the associated die attach material, e.g., solder reflow, sinter, etc.

FIG. 2E illustrates a conductive member 210e including a barrier 220e that, as with the barrier 220d, protrudes from a primary surface of the barrier 220e. In this example, the barrier 220e is triangular shaped. FIG. 2F illustrates a conductive member 210f that has a barrier 220f that protrudes from a primary surface of the conductive member 210f. In this example, the barrier 220f is square or rectangular shaped. FIG. 2G illustrates a conductive member 210g that has a barrier 220g that protrudes from a primary surface of the conductive member 210g. In this example, the barrier 220g is semi-circular shaped.

While the example barriers of FIGS. 2D to 2E respectively include a single barrier structure (protrusion), in some examples, such barrier can include a plurality of barrier structures. Further, the example barriers of FIG. 2D to 2G, e.g., if used in place of the barrier 220 in FIG. 2, will inhibit the outflow of DA adhesive 240a and DA adhesive 240b, e.g., during die placement and adhesive curing, by providing a physical barrier to outflow of DA adhesive. Accordingly, the barriers 220d to 220g can prevent bridging of the DA adhesive 240a with the DA adhesive 240b. Furthermore, the barriers 220d to 220g can limit respective surface areas of the DA adhesive 240a and the DA adhesive 240b that are exposed beyond the respective edges of the semiconductor die 250a and the semiconductor die 250b that are proximate (e.g., closest to) the barrier. In some implementations, the barriers of FIGS. 2E to 2G can be monolithically integrated (monolithically formed) with their respective conductive members.

FIGS. 3A to 3C are diagrams schematically illustrating examples of barriers blocking and/or impeding outflow of die attach adhesive outflow in respective semiconductor device assemblies. FIG. 3A illustrates an assembly 300a that includes a conductive member 310a, which can be an implementation of the conductive member 210c of FIG. 2C. That is, in this example, the conductive member 310a has a barrier 320a, which is a groove with a semi-circular shape. In some implementations, the conductive member 210a of FIG. 2A, the conductive member 210b of FIG. 2B, or a conductive member having a grooved barrier of a different configuration, such as those described herein, could be included in the assembly 300a.

As shown in FIG. 3A, the assembly 300a also includes a conductive adhesive 340a1, a conductive adhesive 340b1, a semiconductor die 350a1, and a semiconductor die 350b1. In the view of FIG. 3A, the assembly 300a is illustrated after performing a high temperature operation, e.g., at greater than 300° C., to cure the conductive adhesive 340a1 and the conductive adhesive 340b1 to respectively couple the semiconductor die 350a1 and the semiconductor die 350b1 with corresponding first and second die attach surfaces of the conductive member 310a, e.g., as defined by the barrier 320a.

As further shown in FIG. 3A, as a result of respective placement of the semiconductor die 350a1 and the semiconductor die 350b1 on the conductive adhesive 340a1 and the conductive adhesive 340b1 and/or an associated high-temperature curing operation, outflow of the conductive adhesive 340a1 and the conductive adhesive 340b1 can occur. As illustrated in FIG. 3A, this outflow of conductive adhesive can be collected by, e.g., flow into, the barrier 320a, which can prevent bridging of the conductive adhesive 340a1 with the conductive adhesive 340b1, as well as limit respective exposed areas of the conductive adhesive 340a1 and the conductive adhesive 340b1 beyond the edges of the semiconductor die 350a1 and the semiconductor die 350b1 proximate the barrier 320a.

FIG. 3B illustrates an assembly 300b that includes a conductive member 310b, which can be an implementation of the conductive member 210d of FIG. 2D. In this example, the conductive member 310b has a barrier 320b, which includes a solder resistor that protrudes from a primary surface of the conductive member 310b. In some implementations, other materials can be used to form the 320b, such as a copper film that is brazed to the barrier 320b.

As shown in FIG. 3B, the assembly 300b also includes a conductive adhesive 340a2, a conductive adhesive 340b2, a semiconductor die 350a2, and a semiconductor die 350b2. In the view of FIG. 3B, the assembly 300b is illustrated after performing a high temperature operation, e.g., at greater than 300° C., to cure the conductive adhesive 340a2 and the conductive adhesive 340b2 to respectively couple the semiconductor die 350a2 and the semiconductor die 350b2 with corresponding first and second die attach surfaces of the conductive member 310b, e.g., as defined by the barrier 320b.

As shown in FIG. 3B, as a result of respective placement of the semiconductor die 350a2 and the semiconductor die 350b2 on the conductive adhesive 340a2 and the conductive adhesive 340b2 and/or an associated high-temperature curing operation, outflow of the conductive adhesive 340a2 and the conductive adhesive 340b2 can occur. As illustrated in FIG. 3B, this outflow of conductive adhesive can be blocked, e.g., physically inhibited, by the barrier 320b, which can prevent bridging of the conductive adhesive 340a2 with the conductive adhesive 340b2, as well as limit respective exposed areas of the conductive adhesive 340a2 and the conductive adhesive 340b2 beyond the edges of the semiconductor die 350a2 and the semiconductor die 350b2 proximate the barrier 320b.

FIG. 3C illustrates an assembly 300c that includes a conductive member 310c, which can be an implementation of the conductive member 210g of FIG. 2G. That is, in the example of FIG. 3C, the conductive member 310c has a barrier 320c, which is a protrusion with a semi-circular shape. In some implementations, the conductive member 210e of FIG. 2E, the conductive member 210F of FIG. 2F, or a conductive member having a protruding barrier of a different configuration could be included in the assembly 300c.

As shown in FIG. 3C, the assembly 300c also includes a conductive adhesive 340a3, a conductive adhesive 340b3, a semiconductor die 350a3, and a semiconductor die 350b3. In the view of FIG. 3C, the assembly 300c is illustrated after performing a high temperature operation, e.g., at greater than 300° C., to cure the conductive adhesive 340a3 and the conductive adhesive 340b3 to respectively couple the semiconductor die 350a3 and the semiconductor die 350b3 with corresponding first and second die attach surfaces of the conductive member 310c, e.g., as defined by the barrier 320c.

As further shown in FIG. 3C, as a result of respective placement of the semiconductor die 350a3 and the semiconductor die 350b3 on the conductive adhesive 340a3 and the conductive adhesive 340b3 and/or an associated high-temperature curing operation, outflow of the conductive adhesive 340a3 and the conductive adhesive 340b3 can occur. As illustrated in FIG. 3C, this outflow of conductive adhesive can be blocked, e.g., physically inhibited, by the barrier 320c, which can prevent bridging of the conductive adhesive 340a3 with the conductive adhesive 340b3, as well as limit respective exposed areas of the conductive adhesive 340a3 and the conductive adhesive 340b3 beyond the edges of the semiconductor die 350a3 and the semiconductor die 350b3 proximate the barrier 320c.

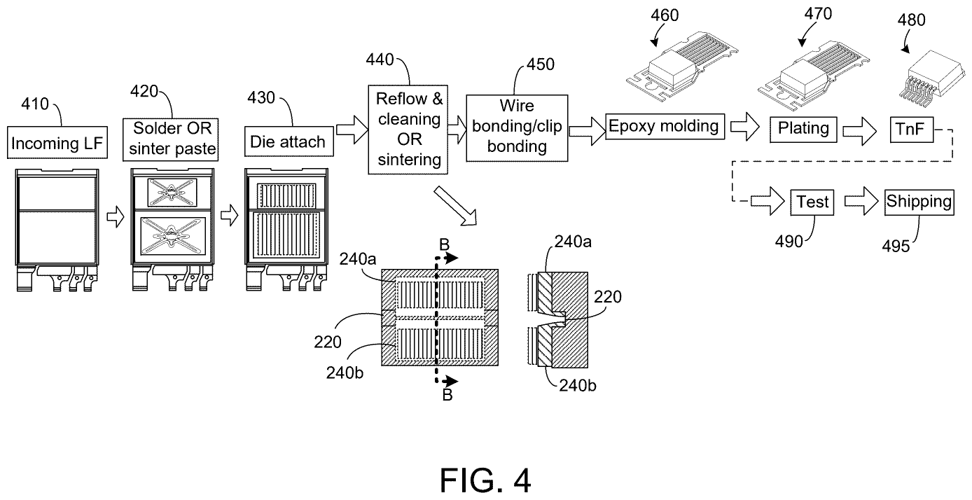

FIG. 4 is a flowchart including schematic diagrams illustrating an example process flow (method 400) for producing a semiconductor device assembly, such as the semiconductor device assemblies described herein. As shown in FIG. 4, at operation 410, the method 400 can start with a leadframe including a conductive member having a primary surface to which one or more semiconductor die can be attached.

In the example of FIG. 4, a leadframe including a die attach paddle (conductive member) is shown. However, in some implementations, the conductive member can be a metal layer that is included in a direct-bonded metal (DBM) substrate, such as direct bonded copper (DBC) substrate. A DBM substrate can include an insulator layer (e.g., a ceramic layer), a first metal layer (e.g., a patterned metal layer including a conductive member and electrically conductive traces) disposed on a first side of the insulator layer, and a second metal layer (e.g., for attaching a heat sink) disposed on an opposite side of the insulator layer. In some implementations, such as DBC implementations, the first metal layer and the second metal layer are copper layers. Example implementations including a DBM substrate are shown in FIGS. 5A-5B and FIGS. 6A-6B. In some implementations, the method 400 can be performed with a DBM substrate rather than a leadframe.

In the example of FIG. 4, depending on the particular implementation, the die attach paddle can include a barrier that is monolithically formed with the die attach paddle. In some implementations, the barrier can be a protrusion that is coupled with the die attach paddle at operation 410, e.g., a solder resistor or other material, or the barrier can be a groove that is formed in the die attach paddle at operation 410. At operation 420, the method 400 includes applying (depositing) conductive adhesive to the die attach surfaces of the die attach paddle. As shown in FIG. 4, operation 420 can include printing solder paste or sinter paste on the die attach paddle, e.g., on separate die attach surfaces. In some implementations, other DA adhesive materials can be used, such as conductive epoxies or other resin based materials.

At operation 430, the method 400 includes placement (e.g., picking and placing) of respective semiconductor die on the conductive adhesive that is applied, dispensed, deposited, printed, etc. at operation 420. At operation 440, an adhesive cure operation is performed. In example implementations, the cure operation can include a solder reflow and cleaning, or can include a sintering operation, such as a pressure-sintering operation. For instance, a pressure sintering operation can include applying pressure to the semiconductor die, e.g., with a pressure plate or other sintering tool. While applying pressure, the in-process assembly is heated to a sintering temperature (e.g., greater than 300° C.) to couple (sinter) the semiconductor die placed at operation 430 to their respective die attach surface(s) on the die attach paddle. In some implementations, after pressure sintering is completed, the pressure plate and/or other tooling can be removed, and subsequent processing can be performed.

At operation 450, the method 400 includes forming wire bonds and/or coupling conductive clips (or other conductive elements) with the leadframe and/or the attached semiconductor die. At operation 460, an encapsulation process is performed, such as with an epoxy molding compound, to encapsulate at least portions of the device assembly, e.g., to protect them from environmental elements. In this example, and other examples disclosed herein, because the outflow barrier reduces (blocks, etc.) outflow of the conductive die attach adhesive material to prevent bridging, an area of the DA material that is contacted by the epoxy molding compound can be reduced or limited as well. Accordingly, risk of poor DA adhesive coverage die tilt, and/or epoxy molding compound delamination can be reduced, which can also reduce or prevent occurrence of associated reliability issues, such as those described herein.

The method 400 further includes, at operation 470, plating signal leads of the assembly. At operation 480, the method 400 includes a trim and form operation, to shape signal lead of the assembly as appropriate for a given application or assembly configuration. At operation 490, the method 400 includes testing functionality of the assembly. At operation 496, the method includes shipping devices that pass functional test, e.g., to a customer.

As shown in the diagrams of FIG. 4 that are associated with the operation 440, (referenced with like reference numbers as FIG. 2), the barrier 220 (e.g., a grooved barrier in this example) can inhibit outflow of die attach adhesive material 240a and 240b by collecting (acting a reservoir) for excess (outflowed) adhesive material. In these diagrams, the diagram on the left is a top-down schematic view, while the diagram on the right is a cross-sectional schematic view along the section line B-B in the left diagram. In some implementations, other types of barriers (protrusions), such as those described herein, can prevent adhesive material outflow by physically blocking that outflow. That is, raised or protruding barriers can prevent DA material outflow by acting as dam, or physical barrier to stop outflow of the DA material.

FIGS. 5A and 5B are diagrams illustrating, respectively, top and side views of an example semiconductor device assembly (assembly 500) including outflow barriers. FIG. 5A is a top-down view of the assembly 500, while FIG. 5B is a side view of the assembly 500. In this example, the assembly 500 includes a DBM substrate 505. A conductive member 510 and a conductive member 515 (e.g., separate portions of a patterned metal layer) are included in the DBM substrate 505, e.g., disposed on a ceramic layer of the DBM substrate 505. The conductive member 510 includes a barrier 520 that includes two V-shaped grooves formed in the conductive member 510. The conductive member 515 includes a barrier 525 that is a single V-shaped groove. The assembly 500 further includes a plurality of signal leads 530 that are coupled, respectively, with the conductive member 510 and the conductive member 515.

A conductive adhesive 540 is disposed on the conductive member 510, and a semiconductor die 550 is disposed on the conductive adhesive 540. As shown in FIG. 5, the barrier 520 extends around (proximate to) a perimeter of the semiconductor die 550 (and a corresponding perimeter of the conductive adhesive 540). In such as arrangement, the barrier 520 prevents outflow of conductive adhesive 540, which can prevent bridging with conductive adhesive used to couple signal leads 530 with the conductive member 510, prevent interference with formation of wire bonds 557, and limit an area of an interface of the conductive adhesive 540 with a molding compound used to encapsulate the assembly 500.

A conductive adhesive 545 is disposed on the conductive member 515, and a semiconductor die 555 is disposed on the conductive adhesive 540. As shown in FIG. 5, the barrier 525 extends along (proximate to) a single edge of the semiconductor die 555 (and a corresponding edge of the conductive adhesive 545). In such an arrangement, the barrier 525 prevents outflow of conductive adhesive 545, which can prevent bridging with conductive adhesive used to couple signal leads 530 with the conductive member 515, and limit an area of an interface of the conductive adhesive 545 with a molding compound used to encapsulate the assembly 500.

FIGS. 6A and 6B are diagrams illustrating, respectively, top and side views of another example semiconductor device assembly (assembly 600) including outflow barriers. FIG. 6A is a top-down view of the assembly 600, while FIG. 6B is a side view of the assembly 600. In this example, the assembly 600 includes a DBM substrate 605. A conductive member 610 and a conductive member 615 (e.g., separate portions of a patterned metal layer) are included in the DBM substrate 605, e.g., disposed on a ceramic layer of the DBM substrate 605. The conductive member 610 includes a barrier 620a that includes a first plurality of wire bonds tails disposed on the conductive member 610, and a barrier 620b that includes a second plurality of wire bond tails disposed on the conductive member 610. The conductive member 615 includes a barrier 625 that includes a third plurality of wire bond tails.

In some implementations, the wire bond tails of the barriers 620a, 620b and 625 can be produced by forming wedge bonds, respectively, on the conductive member 610 and the conductive member 615 with a wire bonding apparatus. After forming each wedge bond, the wire (e.g., supplied from a wire spool) used to form the wedge bond can be cut, or sheared off to form a corresponding wire bond tail. The assembly 600 further includes a plurality of signal leads 630 that are coupled, respectively, with the conductive member 610 and the conductive member 615.

A conductive adhesive 640 is disposed on the conductive member 610, and a semiconductor die 650 is disposed on the conductive adhesive 640. As shown in FIG. 6, the barrier 620a extends along (proximate to) a first edge of the semiconductor die 650 (and a corresponding edge of the conductive adhesive 640). The barrier 620b extends along (proximate to) a second edge of the semiconductor die 650 (and a corresponding edge of the conductive adhesive 640). In such an arrangement, the barriers 620a and 620b prevent outflow of conductive adhesive 640, which can prevent bridging with conductive adhesive used to couple signal leads 630 with the conductive member 610, prevent interference with formation of wire bonds 657, and limit an area of an interface of the conductive adhesive 640 with a molding compound used to encapsulate the assembly 600.

A conductive adhesive 645 is disposed on the conductive member 615, and a semiconductor die 655 is disposed on the conductive adhesive 640. As shown in FIG. 6, the barrier 625 extends along (proximate to) a single edge of the semiconductor die 655 (and a corresponding edge of the conductive adhesive 645). In such as arrangement, the barrier 625 prevents outflow of conductive adhesive 645, which can prevent bridging with conductive adhesive used to couple signal leads 630 with the conductive member 615, and limit an area of an interface of the conductive adhesive 645 with a molding compound used to encapsulate the assembly 600. In the example assemblies 500 and 600, the barriers 520, 525, 620a, 620b and 625 define adhesive KOZs, which can prevent the issues described herein that can occur as a result of conductive adhesive outflow.

The example semiconductor device assemblies described herein can be implemented with a hybrid die configuration. For instance, instance, in some implementations an assembly may include multiple semiconductor die of different types. For example, in a hybrid die assembly configuration, the assembly may include a first semiconductor die that is implemented in silicon carbide (SiC) and a second semiconductor die that is implemented in silicon. Other combinations of die implemented in other semiconductor materials can also be used, e.g., in addition to, or in place of the examples above. In another example, an assembly can include a discrete semiconductor device, for example, a power transistor, a silicon carbide (SiC) MOSFET, or another device. And a fast-recovery diode implemented in silicon, or other semiconductor material.

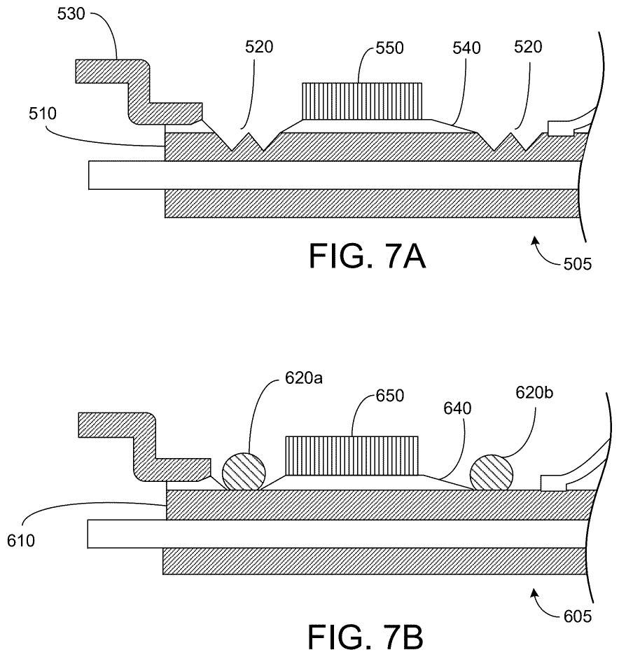

FIG. 7A is a magnified view of a portion of the assembly 500 of FIGS. 5A and 5B. Specifically, FIG. 7A illustrates the left side of the view of the assembly 500 in FIG. 5B.

Accordingly, FIG. 7A is referenced with like reference numbers as FIGS. 5A and 5B. As the view of FIG. 7A illustrates a magnified portion of the assembly 500, the details of assembly 500 are not repeated again with respect FIG. 7A. However, in FIG. 7A, the adhesive KOZ associated with barrier 520 (on left and right sides of the 550) is indicated by vertically arranged ovals in FIG. 7A.

FIG. 7B is a magnified view of a portion of the assembly 600 of FIGS. 6A and 6B. Specifically, FIG. 7B illustrates the left side of the view of the assembly 600 in FIG. 6B. Accordingly, FIG. 7B is referenced with like reference numbers as FIGS. 6A and 6B. As the view of FIG. 7B illustrates a magnified portion of the assembly 600, the details of assembly 600 are not repeated again with respect FIG. 7B. However, in FIG. 7B, the adhesive KOZs respectively associated with the barrier 620a and the barrier 620b are indicated by vertically arranged ovals in FIG. 7B.

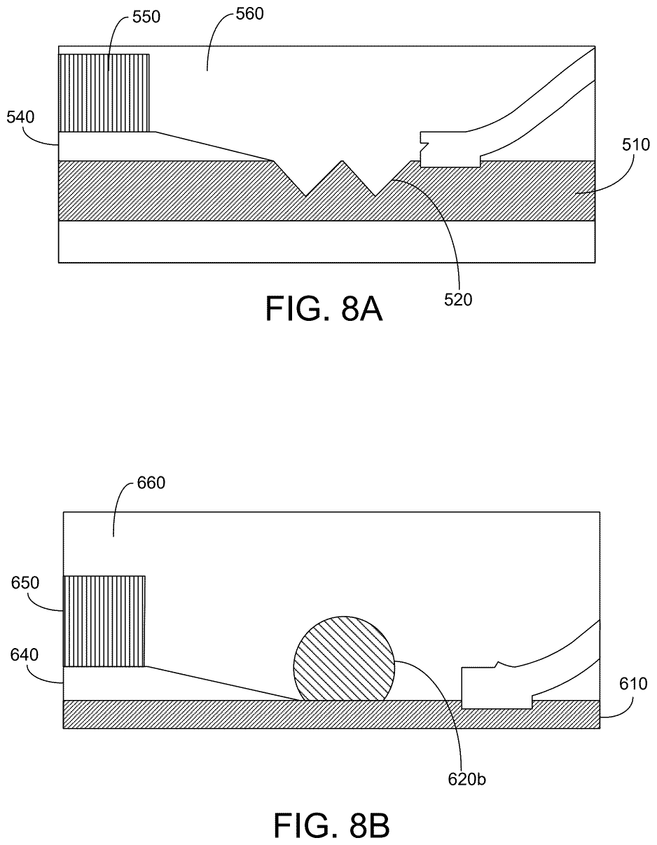

FIG. 8A is a further magnified view of a portion of the assembly 500 shown in FIG. 7A after molding compound encapsulation. The elements of the assembly 500 of FIG. 7A shown in FIG. 8 A are referenced with same reference numbers. The view of FIG. 8A further illustrates a molding compound 560 that is used to encapsulate at least portions of the assembly 500. As shown in FIG. 8A, an area of an interface between the conductive adhesive 540 and the molding compound 560 is limited by the barrier 520 preventing outflow of the conductive adhesive 540 into an associated KOZ.

FIG. 8B is a further magnified view of a portion of the assembly 600 shown in FIG. 7B after molding compound encapsulation. The elements of the assembly 600 of FIG. 7B shown in FIG. 8B are referenced with same reference numbers. The view of FIG. 8B further illustrates a molding compound 660 that is used to encapsulate at least portions of the assembly 600. As shown in FIG. 8B, an area of an interface between the conductive adhesive 640 and the molding compound 660 is limited by the barrier 620b preventing outflow of the conductive adhesive 640 into an associated KOZ.

In a general aspect, a semiconductor device assembly includes a conductive member, a conductive adhesive disposed on the conductive member, and a semiconductor die disposed on the conductive adhesive. The conductive adhesive couples the semiconductor die with the conductive member. The device assembly further includes a barrier included in the conductive member. The barrier is proximate to an edge of the semiconductor die and configured to inhibit outflow of the conductive adhesive.

Implementations can include one or more of the following features or aspects, alone or in combination. For example, the conductive adhesive can be a first conductive adhesive, and the semiconductor die can be a first semiconductor die. The barrier can define, and be disposed between a first die attach surface of the conductive member, and a second die attach surface of the conductive member. The first semiconductor die can be coupled with the first die attach surface. The semiconductor device assembly can include a second conductive adhesive disposed on the second die attach surface proximate the barrier, and a second semiconductor die disposed on the second conductive adhesive. The second conductive adhesive can couple the second semiconductor die with the second die attach surface.

The barrier can include a groove formed in the conductive member. The barrier can include a plurality of grooves formed in the conductive member.

The barrier can include a protrusion extending from a surface of the conductive member. The protrusion can be monolithically formed with the conductive member. The protrusion can include a solder resistor disposed on and coupled with the conductive member. The solder resistor can have a melting point that is greater than a melting point of the conductive adhesive. The protrusion can include a wire-bond tail.

The protrusion can be a first protrusion, and the barrier can include a plurality of protrusions.

The edge of the semiconductor die can be a first edge of the semiconductor die. The barrier can be further proximate to at least one of a second edge of the semiconductor die, a third edge of the semiconductor die, or a fourth edge of the semiconductor die.

The conductive member can be a die attach paddle of a leadframe. The conductive member can be a metal layer of a direct-bonded metal substrate.

The barrier can physically block outflow of the conductive adhesive. The barrier can collect outflow of the conductive adhesive.

The semiconductor device assembly can include a molding compound encapsulating the semiconductor die, the conductive adhesive and at least a portion of the conductive member.

The conductive adhesive can be one of a solder material or a sintering material with a melting point greater than 300° Celsius.

In another general aspect, a semiconductor device assembly includes a conductive member having a primary surface arranged along a transverse axis and a longitudinal axis, and a barrier included in the conductive member. The barrier is arranged along the transverse axis and extends from a first edge of the conductive member to a second edge of the conductive member opposite the first edge. The barrier divides the primary surface into a first die attach surface and a second die attach surface. The device assembly further includes a first conductive adhesive disposed on the first die attach surface proximate the barrier, and a first semiconductor die disposed on the first conductive adhesive. The first conductive adhesive couples the first semiconductor die with the first die attach surface. The device assembly also includes a second conductive adhesive disposed on the second die attach surface proximate the barrier, and a second semiconductor die disposed on the second conductive adhesive. The second conductive adhesive couples the second semiconductor die with the second die attach surface. The barrier is configured to inhibit bridging of the first conductive adhesive with the second conductive adhesive.

Implementations can include one or more of the following features or aspects, alone or in combination. For example, the barrier can include at least one groove formed in the conductive member on the primary surface of the conductive member.

The barrier can include at least one protrusion extending from the primary surface of the conductive member.

The conductive member can be one of a die attach paddle of a leadframe, or a metal layer of a direct-bonded metal substrate.

The semiconductor device assembly can include a molding compound encapsulating, at least, the first semiconductor die, the first conductive adhesive, the second semiconductor die, the second conductive adhesive, the first die attach surface and the second die attach surface.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A semiconductor device assembly comprising:
a conductive member;
a conductive adhesive disposed on the conductive member;
a semiconductor die disposed on the conductive adhesive, the conductive adhesive coupling the semiconductor die with the conductive member; and
a barrier included in the conductive member, the barrier being proximate to an edge of the semiconductor die and configured to inhibit outflow of the conductive adhesive.

2. The semiconductor device assembly of claim 1, wherein:
the conductive adhesive is a first conductive adhesive;
the semiconductor die is a first semiconductor die; and
the barrier defines, and is disposed between:
a first die attach surface of the conductive member; and
a second die attach surface of the conductive member,
the first semiconductor die being coupled with the first die attach surface, the semiconductor device assembly further comprising:
a second conductive adhesive disposed on the second die attach surface proximate the barrier; and
a second semiconductor die disposed on the second conductive adhesive, the second conductive adhesive coupling the second semiconductor die with the second die attach surface.

3. The semiconductor device assembly of claim 1, wherein the barrier includes a groove formed in the conductive member.

4. The semiconductor device assembly of claim 1, wherein the barrier includes a plurality of grooves formed in the conductive member.

5. The semiconductor device assembly of claim 1, wherein the barrier includes a protrusion extending from a surface of the conductive member.

6. The semiconductor device assembly of claim 5, wherein the protrusion is monolithically formed with the conductive member.

7. The semiconductor device assembly of claim 5, wherein the protrusion includes a solder resistor disposed on and coupled with the conductive member, the solder resistor having a melting point that is greater than a melting point of the conductive adhesive.

8. The semiconductor device assembly of claim 5, wherein the protrusion includes a wire-bond tail.

9. The semiconductor device assembly of claim 5, wherein the protrusion is a first protrusion, the barrier including a plurality of protrusions.

10. The semiconductor device assembly of claim 1, wherein the edge of the semiconductor die is a first edge of the semiconductor die, the barrier being further proximate to at least one of:
a second edge of the semiconductor die;
a third edge of the semiconductor die; or
a fourth edge of the semiconductor die.

11. The semiconductor device assembly of claim 1, wherein the conductive member is a die attach paddle of a leadframe.

12. The semiconductor device assembly of claim 1, wherein the conductive member is a metal layer of a direct-bonded metal substrate.

13. The semiconductor device assembly of claim 1, wherein the barrier physically blocks outflow of the conductive adhesive.

14. The semiconductor device assembly of claim 1, wherein the barrier collects outflow of the conductive adhesive.

15. The semiconductor device assembly of claim 1, further comprising a molding compound encapsulating the semiconductor die, the conductive adhesive and at least a portion of the conductive member.

16. The semiconductor device assembly of claim 1, wherein the conductive adhesive is one of a solder material or a sintering material having a melting point of greater than or equal to 300° Celsius.

17. A semiconductor device assembly comprising:
a conductive member having a primary surface arranged along a transverse axis and a longitudinal axis;
a barrier included in the conductive member, the barrier being arranged along the transverse axis and extending from a first edge of the conductive member to a second edge of the conductive member opposite the first edge, the barrier dividing the primary surface into a first die attach surface and a second die attach surface;
a first conductive adhesive disposed on the first die attach surface proximate the barrier;
a first semiconductor die disposed on the first conductive adhesive, the first conductive adhesive coupling the first semiconductor die with the first die attach surface;
a second conductive adhesive disposed on the second die attach surface proximate the barrier; and
a second semiconductor die disposed on the second conductive adhesive, the second conductive adhesive coupling the second semiconductor die with the second die attach surface, the barrier being configured to inhibit bridging of the first conductive adhesive with the second conductive adhesive.

18. The semiconductor device assembly of claim 17, wherein the barrier includes at least one groove formed in the conductive member on the primary surface of the conductive member.

19. The semiconductor device assembly of claim 17, wherein the barrier includes at least one protrusion extending from the primary surface of the conductive member.

20. The semiconductor device assembly of claim 17, wherein the conductive member is one of:
a die attach paddle of a leadframe; or
a metal layer of a direct-bonded metal substrate.

21. The semiconductor device assembly of claim 17, further comprising a molding compound encapsulating, at least, the first semiconductor die, the first conductive adhesive, the second semiconductor die, the second conductive adhesive, the first die attach surface and the second die attach surface.
